(19) United States
(12) Patent Application Publication
(10) Pub. No.: US 2026/0073975 A1
(43) Pub. Date: Mar. 12, 2026

(54) SEMICONDUCTOR STORAGE DEVICE

(71) Applicant: Kioxia Corporation, Tokyo (JP)

(72) Inventor: Daisaburo TAKASHIMA, Yokohama Kanagawa (JP)

(73) Assignee: Kioxia Corporation, Tokyo (JP)

(21) Appl. No.: 19/072,280

(22) Filed: Mar. 6, 2025

(30) Foreign Application Priority Data
Sep. 10, 2024 (JP) 2024-156782

(51) Int. Cl. G11C 11/4096; G11C 11/408; G11C 11/4091

(52) U.S. Cl. CPC G11C 11/4096; G11C 11/4085; G11C 11/4091

(57) ABSTRACT

Memory cells correspond to crossing positions of word lines and bit lines and are formed by using oxide semiconductor. A word-line controller changes a voltage of a first word line selected in accordance with a first address to activate or deactivate the first word line. A sense amplifier detects and latches data of first memory cells connected to the first word-line. A read circuit reads out data latched by the sense amplifier to outside successively in accordance with second addresses. In a read operation, after activation of the first word line, the sense amplifier latches the data of the first memory cells. Before the read circuit ends a successive read operation in which the read circuit successively reads out the data of the first memory cells from the sense amplifier in accordance with the second addresses, the word-line controller deactivates the first word line.

### CROSS REFERENCE TO RELATED APPLICATIONS

This application is based upon and claims the benefit of priority from the prior Japanese Patent Application No. 2024-156782, filed on Sep. 10, 2024, the entire contents of which are incorporated herein by reference.

### FIELD

The embodiments of the present invention relate to a semiconductor storage device.

### BACKGROUND

In a DRAM (Dynamic Random Access Memory), a memory cell is constituted by a capacitor and a transistor. Use of oxide semiconductor for the transistor of this memory cell has been studied.

### BRIEF DESCRIPTION OF THE DRAWINGS

FIG. 1 is a block diagram illustrating a configuration example of a memory device according to a first embodiment;

FIG. 2 is a circuit diagram illustrating a configuration example of a memory cell array;

FIG. 3 is a block diagram illustrating a configuration example of sense amplifiers and bit lines;

FIG. 4 is a block diagram illustrating a configuration example of the sense amplifiers and the bit lines;

FIG. 5 is a timing chart illustrating an operation example of the memory device according to the first embodiment;

FIG. 6 is a diagram illustrating voltages applied to a memory cell in a read operation and a write operation according to the first embodiment;

FIG. 7 is a diagram illustrating voltages applied to the memory cell in a standby state according to the first embodiment;

FIG. 8 is a timing chart illustrating an operation example of a memory device according to a second embodiment;

FIG. 9 is a block diagram illustrating a configuration example of a memory device according to a third embodiment;

FIG. 10 is a timing chart illustrating a refresh operation of a memory device according to a fourth embodiment;

FIG. 11 is a table representing an example of a refresh operation according to the fourth embodiment; and

FIG. 12 is a block diagram illustrating a configuration example of a row control circuit, a column control circuit, and a memory cell according to a fifth embodiment.

### DETAILED DESCRIPTION

In general, according to the embodiment, a semiconductor storage device comprises a plurality of word lines and a plurality of bit lines. A plurality of memory cells are provided to correspond to crossing positions of the word lines and the bit lines and formed by using oxide semiconductor. A word-line control circuit is configured to change a voltage of a first word line selected from the word lines in accordance with a first address to activate or deactivate the first word line. A sense amplifier circuit is connected to the bit lines and configured to detect and latch data of a plurality of first memory cells connected to the first word line. A read circuit is configured to read out data latched by the sense amplifier circuit to outside successively in accordance with a plurality of second addresses. In a read operation, the sense amplifier circuit latches the data of the first memory cells after activation of the first word line. The word-line control circuit deactivates the first word line before the read circuit ends a successive read operation of successively reading out the data of the first memory cells from the sense amplifier circuit in accordance with the second addresses. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First Embodiment

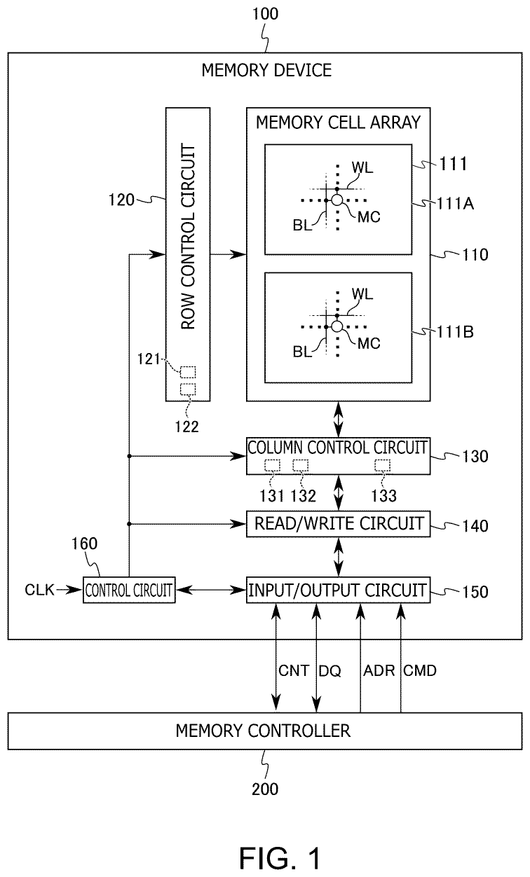

FIG. 1 is a block diagram illustrating a configuration example of a memory device 100 according to a first embodiment. The memory device 100 according to the first embodiment is a DRAM (Dynamic Random Access Memory), for example.

The memory device 100 as a semiconductor storage device is electrically connected to an external memory controller 200. The memory device 100 is configured to allow reading and writing of data therefrom/thereto on the basis of an instruction from the memory controller 200. The memory device 100 receives, for example, an address ADR, a command CMD, data DQ, and a control signal CNT from the memory controller 200. The memory device 100 also sends the control signal CNT and the data DQ to the memory controller 200. The memory device 100 includes a memory cell array 110, a row control circuit 120, a column control circuit 130, a read/write circuit 140, an input/output circuit 150, and a control circuit 160, for example.

The memory cell array 110 is a circuit used for data storage. The memory cell array 110 includes a plurality of sub arrays 111. The sub arrays 111 are classified into a pair of sub arrays 111, for example. The sub arrays 111 include a first sub array 111A and a second sub array 111B corresponding to the pair of sub arrays 111. Each sub array 111 includes a plurality of memory cells MC, a plurality of word lines WL, and a plurality of bit lines BL. Each memory cell MC can store data of 1 bit or more therein. Each memory cell MC is provided to correspond to the crossing position of one of the word lines WL and one of the bit lines BL and is connected therebetween. A row address is assigned to each of the word lines WL. A column address is assigned to each of the bit lines BL. Each memory cell MC can be identified by the row address and the column address.

The row control circuit 120 as a word-line control circuit controls wires assigned in the row direction (e.g., the word lines WL) in the memory cell array 110. The row control circuit 120 selects at least one of the word lines WL in accordance with a row address of the addresses ADR (activation). The row control circuit 120 also sets a word line WL not selected in a non-selected state (deactivation). The row control circuit 120 applies a predetermined voltage to each of the selected word line WL and the non-selected word line WL. The row control circuit 120 includes a driver circuit 121 and an address decoder 122, for example. The driver circuit 121 generates a voltage to be applied to the word line WL. The address decoder 122 decodes a row address. The row control circuit 120 selects the word line WL on the basis of the result of decoding by the address decoder 122. The row control circuit 120 may be called “row decoder”.

The column control circuit 130 controls wires assigned in the column direction (e.g., the bit lines BL) in the memory cell array 110. The column control circuit 130 includes an address decoder 131, a column selection circuit 132, and a sense amplifier circuit 133, for example. The address decoder 131 decodes a column address of the addresses ADR. The sense amplifier circuit 133 is provided for each sub array and connected to the bit lines BL included in the sub array. The sense amplifier circuit 133 includes a plurality of sense amplifiers SA the number of which is based on the number of sub arrays and the number of bit lines BL included in each sub array. The configuration of the bit lines BL may be an Open-BL configuration or a Folded-BL configuration.

In a read operation, when a word line WL selected by the row control circuit 120 is activated, data stored in the memory cells MC connected to the selected word line WL is transmitted to the bit lines BL of the corresponding columns. The sense amplifier circuit 133 of each column detects (amplifies) and latches a change in the voltage of the bit line BL corresponding to that column. Meanwhile, since the data in the memory cells MC is eliminated by data reading, the sense amplifier circuit 133 writes back the original data to the memory cells MC with the amplified and latched voltage (restores the data). The read and restore operations described above are performed for the bit lines BL of all the columns included in a selected sub array at the same time. Further, the column selection circuit 132 outputs data of one or more bit lines BL of one or more columns selected by a column address among the data of all the columns latched by the sense amplifier circuit 133, to the read/write circuit 140.

Meanwhile, in a write operation, when the column selection circuit 132 receives write data from the read/write circuit 140, the column selection circuit 132 transfers the write data to the sense amplifier SA of a column selected by a column address. The selected sense amplifier SA latches the write data and transmits the write data to the bit line BL. Accordingly, the sense amplifier SA writes updated data to the memory cell MC. The column control circuit 130 may be called “sense amplifier” or “column decoder”.

The read/write circuit 140 is a circuit that can read data from the memory cell array 110 and can write data to the memory cell array 110. In a data read operation, the read/write circuit 140 receives read data (voltage or current) latched by the sense amplifier circuit 133 from the column control circuit 130. At this time, the read/write circuit 140 successively reads out the data latched by the sense amplifier circuit 133 to outside in accordance with a plurality of column addresses issued successively (burst read).

In data writing, the read/write circuit 140 receives write data (voltage or current) to be written to the memory cell array 110, from outside via the input/output circuit 150 and sends the write data to the sense amplifier circuit 133 of the column control circuit 130. At this time, the read/write circuit 140 causes the sense amplifier circuit 133 to successively latch the write data in accordance with a plurality of column addresses issued successively (burst write). A write circuit and a read circuit may be provided independently of each other.

The input/output circuit 150 is an interface circuit between the memory device 100 and the memory controller 200. The input/output circuit 150 receives the command CMD, the address ADR, the data DQ (e.g., write data), the control signal CNT, and the like from the memory controller 200. The input/output circuit 150 sends the control signal CNT and the data DQ (e.g., read data) to the memory controller 200.

The control circuit 160 controls the row control circuit 120, the column control circuit 130, the read/write circuit 140, and the like on the basis of the command CMD and the control signal CNT. In a case where the memory device 100 is a DRAM, the control circuit 160 performs a refresh operation for refreshing data in the memory cell array 110 in addition to data writing and data reading. The refresh operation is an operation that, immediately after the word lines WL are activated in turn in accordance with row addresses, and data stored in each memory cell MC is read out to the sense amplifier circuit 133 once and latched, writes back (restores) that data to the memory cell MC. The control circuit 160 also controls the row control circuit 120, the column control circuit 130, the read/write circuit 140, and the like at a timing synchronized with a clock signal CLK. That is, in the memory device 100, each of data writing and data reading is performed at a timing synchronized with the clock signal CLK. The clock signal CLK may be generated inside the memory device 100 or supplied from outside. The control circuit 160 may be called “sequencer” or “internal controller”.

The configuration of the memory device 100 is not limited to that described above. For example, the memory device 100 may include a control circuit controlling a refresh operation, a clock generation circuit, an internal voltage generation circuit, and the like. The refresh operation is performed by a refresh instruction indicated by an internally generated signal of the memory device 100 or a signal from outside of the memory device 100.

Next, a circuit configuration of the memory device 100 is explained.

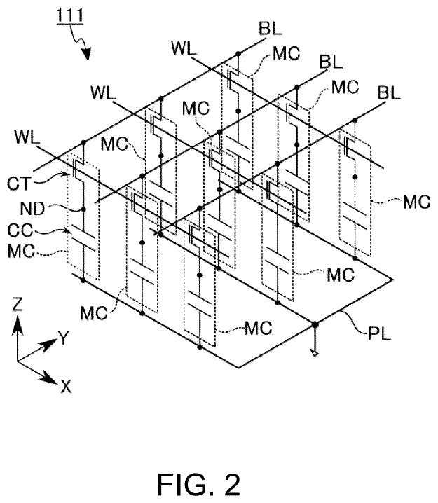

FIG. 2 is a circuit diagram illustrating a configuration example of the memory cell array 110. FIG. 2 illustrates a part of the sub array 111 included in the memory cell array 110. A three-dimensional orthogonal coordinate system illustrated in FIG. 2 corresponds to extending directions of wires. The memory cells MC are arranged in a matrix in a plane (X-Y plane) formed by the X-direction and the Y-direction. The memory cells MC may be arranged three-dimensionally in the X-, Y-, and Z-directions. The sub array 111 further includes a plate line PL. As in a DRAM in which the memory cells MC are arranged two-dimensionally, the Z-direction may be perpendicular to a substrate on which the memory devices 100 are provided. Alternatively, as in a DRAM in which the memory cells MC are arranged three-dimensionally, the X-direction or the Y-direction may be perpendicular to the substrate.

The plate line PL is a wire in the form of a plate extending along the X-Y plane. A plate voltage, for example, ½ of a BL voltage is applied to the plate line PL. Respective one-ends of the memory cells MC are connected to the plate line PL in common. Each of the other ends of the memory cells MC is connected to the corresponding bit line BL. The plate line PL may be called “plate electrode” or “plate layer”. The plate line PL may be divided in accordance with units of control of the sub array 111.

Each memory cell MC includes a cell transistor CT and a cell capacitor CC. The cell transistor CT and the cell capacitor CC of each memory cell MC are connected to each other in series between the corresponding bit line BL and the plate line PL. In each memory cell MC, one of the source and the drain of the cell transistor CT is connected to the corresponding one of the bit lines BL. The other of the source and the drain of the cell transistor CT is connected to a node ND. The gate of the cell transistor CT is connected to the corresponding one of the word lines WL. One electrode of the cell capacitor CC is connected to the node ND and to the other of the source and the drain of the cell transistor CT. The other electrode of the cell capacitor CC is connected to the plate line PL. The cell transistor CT is a field effect transistor (FET) using oxide semiconductor for at least its channel region. The cell capacitor CC is a capacitive element such as an MIM (Metal-Insulator-Metal). The cell transistor CT may simply be called “transistor”. The cell capacitor CC may simply be called “capacitor”.

The cell transistor CT is formed by using oxide semiconductor. The channel material of the cell transistor CT is constituted of an oxide semiconductor material containing an n-type or p-type material system, for example. The channel material contains all or some of indium, gallium, zinc, and oxygen (for example, in the form of indium gallium zinc oxide (IGZO)), for example, and such a channel material can have the n-type conductivity. For example, the channel material can contain tin and oxygen (for example, in the form of tin oxide), antimony and oxygen (for example, in the form of antimony oxide), indium and oxygen (for example, in the form of indium oxide), indium, tin, and oxygen (for example, in the form of indium tin oxide), titanium and oxygen (for example, in the form of titanium oxide), zinc and oxygen (for example, in the form of zinc oxide), indium, zinc, and oxygen (for example, in the form of indium zinc oxide), gallium and oxygen (for example, in the form of gallium oxide), titanium, oxygen, and nitrogen (for example, in the form of titanium oxynitride), ruthenium and oxygen (for example, in the form of ruthenium oxide), or tungsten and oxygen (for example, in the form of tungsten oxide). The thickness of the channel material is 5 to 30 nm, for example.

The material forming the channel region of the cell transistor CT is preferably crystalline oxide semiconductor, for example, but may be amorphous oxide semiconductor. Specific examples of oxide semiconductor may include zinc tin oxide (ZTO), IGZO (also called gallium indium zinc oxide (GIZO)), indium zinc oxide (IZO), ZnOx, InOx, In₂O₃, SnO₂, TiOx, ZnxOyNz, MgxZnyOz, InxZnyOz, InxGayZnzOa, ZrxInyZnzOa, HfxInyZnzOa, SnxInyZnzOa, AlxSnyInzZnaOd, SixInyZnzOa, ZnxSnyOz, AlxZnySnzOa, GaxZnySnzOa, ZrxZnySnzOa, InGaxSiyOz, and other similar materials.

The word lines WL included in the sub array 111 each extend in the X-direction and are arranged in the Y-direction. Each word line WL is connected to the gates of the cell transistors CT of the memory cells MC arranged in the X-direction. In other words, each word line WL is connected to the gates of the cell transistors CT of the memory cells MC to which the same row address is assigned. The gate of the cell transistor CT may be called “control electrode of the memory cell MC”.

The bit lines BL included in the sub array 111 each extend in the Y-direction and are arranged in the X-direction. Each bit line BL is connected to the source or the drain of the cell transistor CT of each of the memory cells MC arranged in the Y-direction. In other words, each bit line BL is connected to the source or the drain of the cell transistor CT of each of the memory cells MC to which the same column address is assigned.

The cell transistor CT is a switch that switches a state in which it electrically connects the cell capacitor CC and the bit line BL to each other and a state in which they are electrically insulated from each other. The cell transistor CT serves as a selection element of the memory cell MC. The cell capacitor CC retains the charge amount corresponding to data of 1 bit or more. The cell capacitor CC serves as a memory element of the memory cell MC. The cell capacitor CC may be a ferroelectric capacitor and a non-volatile polarization retention memory.

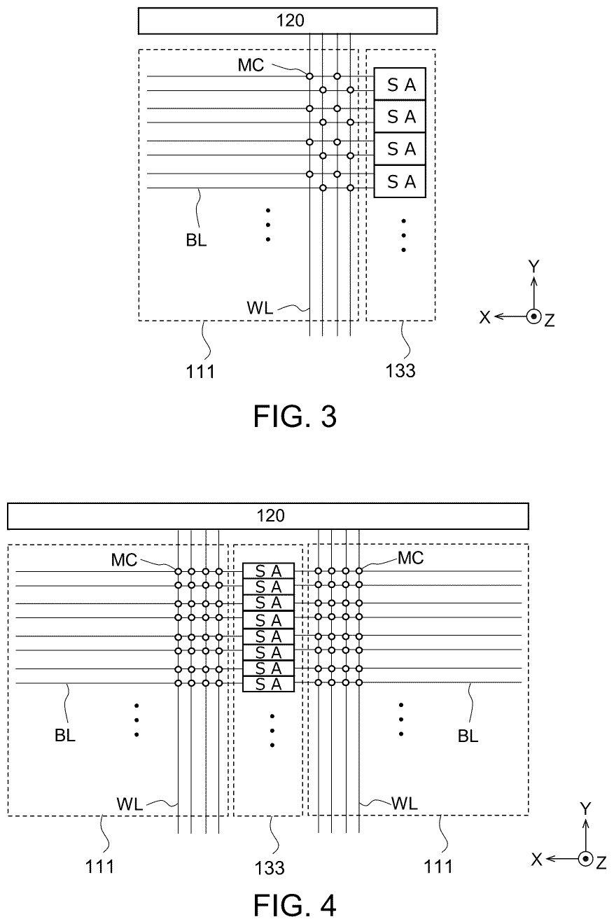

FIGS. 3 and 4 are block diagrams illustrating configuration examples of the sense amplifiers SA and the bit lines BL. The present embodiment has a so-called one cell per bit configuration in which one memory cell MC stores 1-bit data therein.

In FIG. 3, the memory cells MC are arranged in such a manner that one memory cell MC is arranged for two intersection points of the word lines WL with the bit lines BL. In one sub array 111, two bit lines BL adjacent to each other in the Y-direction are connected to one sense amplifier SA. That is, the sense amplifier SA is provided for each pair of bit lines BL in the same sub array 111 (a Folded-BL configuration). In this case, cell data is read out to one of the two bit lines BL. The sense amplifier SA detects data from one of the bit lines BL of the bit line pair by comparing it with data of a reference bit line BL obtained from the other bit line BL.

In FIG. 4, two bit lines BL respectively included in two sub arrays 111 adjacent to each other in the X-direction are connected to one sense amplifier SA. That is, the sense amplifier SA is provided between the two sub arrays 111 adjacent to each other and is provided for each pair of the bit lines BL respectively included in the two sub arrays 111 (an Open-BL configuration). Also in this case, the word line WL of one of right and left sub arrays is selected, and data is read out. The sense amplifier SA detects data from one of the bit lines BL of the bit line pair by comparing it with data of a reference bit line BL obtained from the other bit line BL.

The memory device 100 according to the present embodiment may use any of the bit configurations in FIGS. 3 and 4.

The PBTI (Positive Bias Temperature Instability) characteristics and the NBTI (Negative Bias Temperature Instability) characteristics of a transistor using oxide semiconductor are described here.

In a transistor using oxide semiconductor, when one of a positive bias and a negative bias continues to be applied across the gate and the drain or the gate and the source for a long time, its threshold voltage largely fluctuates. For example, when the positive bias continues to be applied to the transistor for a long time, the threshold voltage of the transistor increases with time of application (PBTI characteristics). Meanwhile, when the negative bias continues to be applied to the transistor for a long time, the threshold voltage of the transistor decreases with time of application (NBTI characteristics). When a fluctuation in the threshold voltage of the cell transistor CT of the memory cell MC is large, the memory cell MC does not operate and becomes a defective bit. Therefore, it is preferable that a fluctuation in the threshold voltage of the cell transistor CT is as small as possible. The change in the threshold voltage described above is caused by trapping or de-trapping of charges to/from an interface between a channel region made of oxide semiconductor and a gate dielectric film. In a case where transfer of hydrogen ions (H+) is a cause of the change in the threshold voltage, the polarity of the change in the threshold voltage is often reverse to the trapping of charges to the interface described above.

When application of the positive or negative bias to the transistor using oxide semiconductor is stopped and the transistor is placed in a no-bias state, the fluctuation in the threshold voltage of the transistor becomes smaller with time and the state of the threshold voltage returns to its original state. Further, when one of the positive bias and the negative bias is applied to the transistor and thereafter the other bias of reverse polarity is applied, the fluctuation in the threshold voltage becomes smaller with time and the state of the threshold voltage returns to its original state. That is, the PBTI characteristics and the NBTI characteristics of the transistor using oxide semiconductor can be recovered by, after application of one polarity bias, stopping application of that bias and then applying the bias of reverse polarity or applying no bias.

Accordingly, a ratio (Duty) of an active time of the word line WL to an inactive time of the word line WL is important for preventing deterioration of the PBTI and NBTI characteristics, depending on gate-drain voltages Vgd or gate-source voltages Vgs in an active state and an inactive state. Duty is a ratio of a time during which a positive bias is applied to the word line WL to a time during which a negative bias is applied to the word line WL (or a time during which no bias is applied) (i.e., active time/inactive time).

For example, in a case where the voltages Vgd or Vgs in the active state and the inactive state are reverse to each other in polarity and are equal to each other in absolute value, Duty is preferably 1. Consequently, the positive bias and the negative bias are evenly applied to the transistor, so that the deterioration (change) of the transistor characteristics can be reduced. In the present embodiment, the row control circuit 120 makes the voltage of the non-selected word line WL other than a selected word line WL1 have a reverse polarity to that of the voltage of the selected word line WL1. That is, the voltages of the word line WL in the active state and the inactive state are made reverse to each other in polarity. Accordingly, the gate-drain voltages Vgd or the gate-source voltages Vgs in the active state and the inactive state are made reverse to each other in polarity. Accordingly, it is preferable that Duty is close to 1.

In a case where the voltage Vgd or Vgs in the inactive state corresponds to no bias, it is preferable that Duty is as small as possible. Consequently, the transistor is placed in the no-bias state for a long time, and it is therefore possible to recover deterioration of the PBTI and NBTI characteristics caused by bias application in the active state.

Next, an operation of the memory device 100 is described. The following description focuses on one of the bit lines BL of a bit line pair, for which data reading from the memory cell MC and data writing are performed.

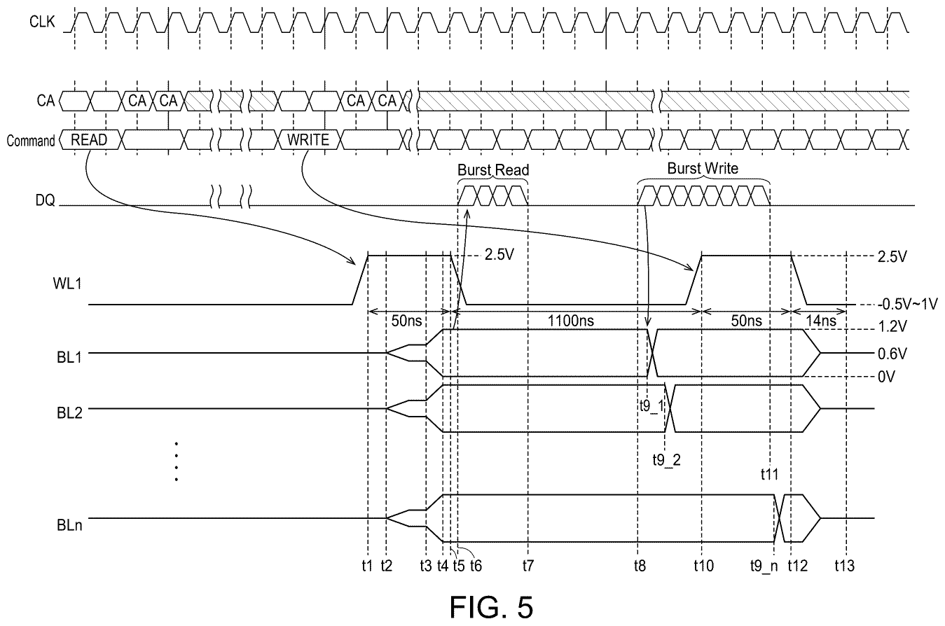

FIG. 5 is a timing chart illustrating an operation example of the memory device 100 according to the first embodiment. In this example, a burst read operation and a burst write operation are continuously performed in this order as an example of a case where the characteristics are deteriorated by PBTI. The burst read operation is an operation in which the read/write circuit 140 successively reads out data transmitted from the memory cells MC to the sense amplifier circuit 133 and latched by the sense amplifier circuit 133 to outside in accordance with a plurality of column addresses issued successively. Data read at one time may be on a bit-by-bit basis or in multiple bit units (e.g., 8 bits). The burst write operation is an operation in which the read/write circuit 140 causes the sense amplifier circuit 133 to successively latch write data from outside in accordance with a plurality of column addresses issued successively. The data latched by the sense amplifier circuit 133 is written to the memory cells MC of a selected row address via the bit lines BL of the respective columns, following the latch. Data written at one time may be on a bit-by-bit basis or in multiple bit units (e.g., 8 bits).

CLK in FIG. 5 represents a clock signal generated outside or inside and supplied to the control circuit 160. CA represents a command address specifying a bank, a row address, a column address, and the like. Command represents a control signal instructing an operation to be performed (for example, a read operation, a write operation, and a refresh operation) to the memory array 110. DQ represents data output from the input/output circuit 150 or data input to the input/output circuit 150.

### Burst Read Operation

The control circuit 160 causes the memory device 100 to operate in synchronization with the clock signal CLK generated outside or inside.

When a read command READ is issued and a row address of a read target is issued, the row control circuit 120 selectively activates the word line WL1 in accordance with the row address. For example, the row control circuit 120 raises the voltage of the word line WL1 to a high level at t1. Accordingly, a plurality of first memory cells MC corresponding to that row address and connected to the word line WL1 are connected to bit lines BL1 to BLn (n is an integer of 2 or more) of columns corresponding thereto.

Data of the first memory cells is transmitted to the corresponding bit lines BL1 to BLn. For example, the voltages of the bit lines BL1 to BLn increase or decrease in accordance with the data logic of the respective first memory cells in a period from t2 to t3 in FIG. 5.

In a period from t3 to t4, the sense amplifier circuit 133 detects (amplifies) the data transmitted to each bit line BL. Further, in a period from t4 to t5, the sense amplifier circuit 133 latches the data transmitted to each bit line BL. At this time, the data of the first memory cells MC of all the columns, which are specified by the row address, is detected and latched in the sense amplifier circuit 133 at substantially the same time. By amplifying and latching the data by the sense amplifier circuit 133, the same data in each column is written back (restored) to the first memory cell MC via the corresponding one of the bit lines BL1 to BLn.

As described above, in a period from t1 to t5, the data of the memory cells MC connected to the word line WL1 is detected and latched by the sense amplifier circuit 133. By this detection and latching, data restoring to the first memory cells MC is completed. Therefore, in the present embodiment, after the sense amplifier circuit 133 has latched the data, the row control circuit 120 deactivates the word line WL1. For example, the row control circuit 120 causes the voltage of the word line WL1 to drop to a low level at t5. Accordingly, the first memory cells MC are disconnected from the bit lines BL1 to BLn. Meanwhile, the sense amplifier circuit 133 maintains a state where it has latched the data of the first memory cells MC.

The control circuit 160 successively issues a plurality of column addresses. In a period from t6 to t7, the read/write circuit 140 successively reads out the data DQ latched by the sense amplifier circuit 133 to outside in accordance with the column addresses issued. That is, the read/write circuit 140 performs the burst read operation. The burst read operation can be performed as long as the sense amplifier circuit 133 has latched data. Accordingly, there is no problem if the word line WL1 is deactivated even in the middle of the burst read operation as long as deactivation is made after the sense amplifier circuit 133 restores the data to the first memory cells MC. That is, there is no problem if the row control circuit 120 deactivates the word line WL1 before t7 at which the read/write circuit 140 ends the burst read operation.

### Burst Write Operation

After issuance of a write command WRITE, the control circuit 160 successively issues a plurality of column addresses.

In a period from t8 to t11, write data DQ is input from outside via the I/O circuit 150. The read/write circuit 140 causes the sense amplifier circuit 133 to successively latch the data DQ in accordance with the column addresses taken in by the command address CA. At this time, the write data DQ is transmitted to a bit line (any of BL1 to BLn) connected to the sense amplifier circuit 133 that has latched the write data DQ.

For example, in a case where the sense amplifier SA corresponding to the bit line BL1 has latched the write data DQ, the bit line BL1 transmits a voltage based on the write data DQ at t9_1. FIG. 5 illustrates an example in which data different from data originally stored in a memory cell is written. In this example, latched data of the sense amplifier SA corresponding to the bit line BL1 has the logic inverted and, associated with this logic inversion, the data of the bit line BL1 also has the logic inverted. However, in a case where the latched data of the sense amplifier SA corresponding to the bit line BL1 is not inverted, the data of the bit line BL1 is non-inverted.

For example, in a case where the sense amplifier SA corresponding to the bit line BL2 has latched the write data DQ, the bit line BL2 transmits a voltage based on the write data DQ at t9_2. In the example of FIG. 5, the latched data of the sense amplifier SA corresponding to the bit line BL2 also has the logic inverted and, associated with this logic inversion, the data of the bit line BL2 also has the logic inverted. However, in a case where the latched data of the sense amplifier SA corresponding to the bit line BL2 is not inverted, the data of the bit line BL2 is non-inverted.

Data of the sense amplifiers SA and the bit lines BL3 to BLn of other columns are also successively updated in accordance with the write data DQ in a similar manner. That is, the read/write circuit 140 performs the burst write operation.

In FIG. 5, data of the bit lines BL1 to BLn is successively updated on a column-by-column basis for the sake of convenience. That is, one column address corresponds to the sense amplifiers SA and the bit line BL for one column. However, one column address may correspond to the sense amplifiers SA and the bit lines BL for a plurality of columns. For example, in a case where one column address corresponds to 8-bit data, 8-bit data DQ is latched by eight sense amplifiers SA at the same time and transmitted to eight bit lines BL respectively corresponding thereto at the same time.

In association with issuance of the write command WRITE, the row control circuit 120 selectively activates the word line WL1 in accordance with the row address that has already been taken in in the Read operation. For example, the row control circuit 120 raises the voltage of the word line WL1 to a high level at t10. Accordingly, the first memory cells MC corresponding to that row address and connected to the word line WL1 are connected to the bit lines BL1 to BLn of columns corresponding thereto. Consequently, data of the bit lines BL1 to BLn is written to the first memory cells MC. At t10, there is no problem if the burst write operation is in progress. In a case where the word line WL1 is activated in the middle of the burst write operation, every time data is written to the sense amplifier SA of a certain column, the data is written to the first memory cell MC via the bit line BL of that column.

At t11, at the time of the end of the burst write operation for the sense amplifier circuit 133, the row control circuit 120 maintains a state in which it has activated the word line WL1. Therefore, data latched by the sense amplifier circuit 133 at the end of the burst write operation can also be written to the first memory cell MC via the bit line BL. That is, in the write operation, it suffices that the row control circuit 120 has activated the word line WL1 specified by the row address at a time at which the burst write operation is finished.

At t12, the row control circuit 120 deactivates the word line WL1. In a period from t12 to t13, the bit lines BL and the like are precharged.

As described above, in the burst write operation, if the word line WL1 is in the active state at a time when all the write data DQ has been latched by the sense amplifier circuit 133, it is possible to write the write data DQ to the first memory cells MC. Therefore, the row control circuit 120 may activate the word line WL1 after the start of the burst write operation, although it is necessary to activate the word line WL1 before the end of the burst write operation. Further, the row control circuit 120 deactivates the word line WL1 after the end of the burst write operation.

As illustrated in FIG. 5, in a case where the write command WRITE has been issued following the read command READ successively, the row control circuit 120 maintains the word line WL1 in the inactive state after data of the first memory cells MC is latched to the sense amplifier circuit 133 at t4 at least until the burst write operation starts at t8. The row control circuit 120 then activates the word line WL1 before the end of the burst write operation at t11. That is, the row control circuit 120 pulses the voltage of the word line WL1 for each read command READ or each write command WRITE.

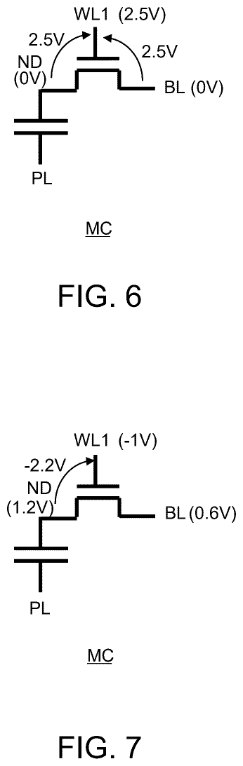

FIG. 6 is a diagram illustrating voltages applied to the memory cell MC in a read operation and a write operation according to the first embodiment. FIG. 7 is a diagram illustrating voltages applied to the memory cell MC in a standby state according to the first embodiment. It is assumed that the voltage of the word line WL1 in the inactive state is −1 to −0.5 V and the voltage of the word line WL1 in the active state is 2.5 V. It is further assumed that the voltage of the node ND is 0 V for data “0” and 1.2 V for data “1”. It is also assumed that the voltage of the bit line BL is maintained to an intermediate voltage of 0.6 V that is between the data “0” and the data “1” in the standby state.

In this case, the maximum value of the voltage Vgd or Vgs of the cell transistor CT is 2.5 V, which is a value in reading or writing of data “0” as illustrated in FIG. 6. If the state in FIG. 6 continues for a long time, the characteristics are deteriorated by PBTI of the cell transistor CT. The minimum value of the voltage Vgd or Vgs of the cell transistor CT is −2.2 V that is a value in the standby state of data “1” as illustrated in FIG. 7. If the standby state in FIG. 7 continues for a long time, the characteristics are deteriorated by NBTI of the cell transistor CT.

In this example, a positive bias up to 2.5 V and a negative bias of −2.2 V at the minimum are applied to the cell transistor CT. In a case where the voltages Vgd or Vgs in the active state and the inactive state are reverse to each other in polarity as described above, it is preferable that Duty is close to 1. Consequently, the positive bias and the negative bias are evenly applied to the transistor, so that the characteristic deterioration of the cell transistor CT can be reduced.

In the memory device 100 according to the present embodiment, as illustrated in FIG. 5, the word line WL1 is activated in response to issuance of the read command READ and is then deactivated before the end of a burst read operation. An active period during which the word line WL1 is made active by the read command READ (from t1 to t5) is 50 ns, for example. Thereafter, the word line WL1 is activated again in response to issuance of the write command WRITE before the end of burst write to the sense amplifier circuit 133, is in the active state at the end of burst write, and is deactivated after the end of burst write. An active period during which the word line WL1 is made active by the write command WRITE (from t10 to t12) is 50 ns, for example. An inactive period from deactivation of the word line WL1 after issuance of the read command READ to activation of the word line WL1 by the write command WRITE (from t5 to t10) is about 1100 ns, for example. After burst write, a precharging period (from t12 to t13) is about 14 ns, for example. The period from t1 to t13 described above serves as units of operation of a read operation and a write operation performed successively. In this case, Duty is about 0.09 ((50 ns×2)/(1100 ns+14 ns)).

As a comparative example, when the read command READ and the write command WRITE have been issued successively by using a conventional technique, the row control circuit 120 makes the word line WL1 active continuously during a period including a period from the start of burst read to the end of burst write. In this case, Duty (active time/inactive time) becomes very large. Therefore, the threshold voltage of the cell transistor CT largely fluctuates, and the deterioration of the characteristics by PBTI becomes remarkable. In a case where the above comparative example is applied to the example of FIG. 5, and the word line WL1 is continuously made active from activation (t1) of the word line WL1 by the read command READ to deactivation (t12) of the word line WL1, Duty is about 86 ((50 ns×2+1100 ns)/14 ns).

Duty in the present embodiment is closer to 1 than that in the comparative example. Therefore, it is found that deterioration of the PBTI characteristics of the cell transistor CT is reduced.

Next, a case where the read command READ or the write command WRITE has been issued alone is described with reference to FIG. 5.

For example, in a case where the read command READ has been issued alone, the row control circuit 120 activates the word line WL1 and, after the sense amplifier circuit 133 latches data, deactivates the word line WL1, similarly to the operations from t1 to t5 in FIG. 5. The active time of the word line WL1 is 50 ns, for example. Thereafter, burst read of data from the sense amplifier circuit 133 is performed and a precharge operation is then performed. A period of burst read depends on the number of column addresses issued and corresponds to reading of only one column address (e.g., 8 ns) at the minimum. The period of the precharge operation is the same as the period from t12 to t13 and is assumed as 14 ns, for example. In this case, the inactive time of the word line WL1 is 22 ns (8 ns+14 ns), for example. Therefore, Duty is about 2.3 (50 ns/(8 ns+14 ns)). As described above, Duty is about 2.3 at most, which is very small as compared with 86 in the comparative example and close to 1. Accordingly, it is found that deterioration of the characteristics by PBTI of the cell transistor CT is reduced. As a result, the lifetime of the memory cell MC can be prolonged, so that the reliability of the memory device 100 can be improved.

### Second Embodiment

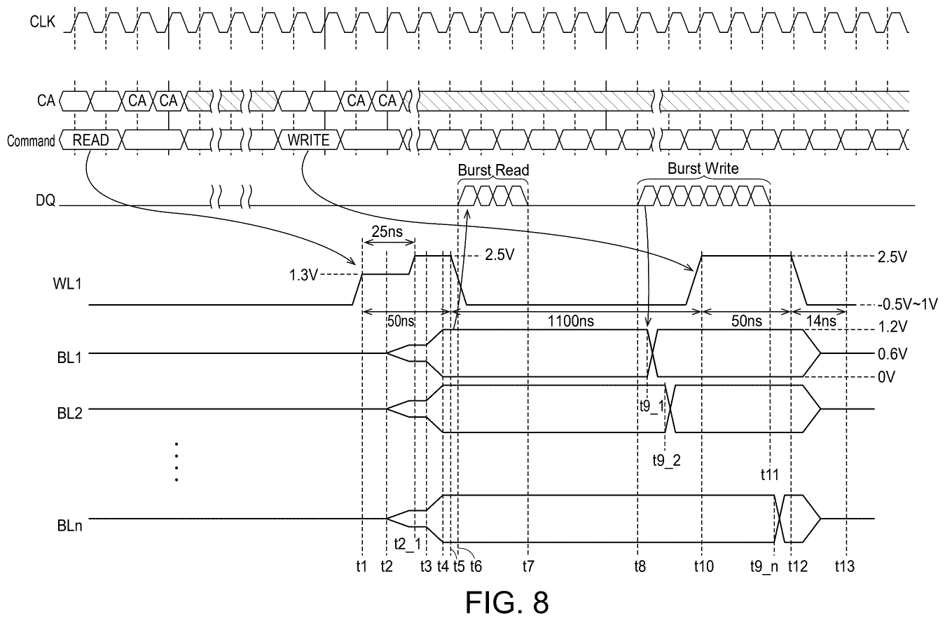

FIG. 8 is a timing chart illustrating an operation example of the memory device 100 according to a second embodiment. In the second embodiment, the row control circuit 120 makes the voltage of the word line WL1 in a period from t1 to t2_1 in which the sense amplifier circuit 133 detects data in a read operation lower than the voltage of the word line WL1 in a period from t2_1 to t5 in which the sense amplifier circuit 133 latches the data and restores the data in the memory cells MC. The voltage of the word line WL1 in the data detection period from t1 to t2_1 is 1.3 V, for example. The voltage of the word line WL1 in the period from t2_1 to t5 in which the sense amplifier circuit 133 latches the data and restores the data in the memory cells MC is 2.5 V, for example. The reason why the voltage of the word line WL1 in the read operation can be made lower than that in the write operation is as follows. If only an operation of reading data of the memory cell MC to the sense amplifier SA is performed, it is also permissible that the potential of the word line WL is relatively low. Meanwhile, in a write operation, it is necessary to write data “1” for which the potential of a bit line becomes high to the memory cell MC. Further, as for the potential of the word line WL, it is necessary to add a voltage equal to or higher than a threshold voltage to this potential of the bit line BL. Therefore, the voltage of the word line WL1 in the read operation can be made lower than that in the write operation. If the potential of the bit line BL in the standby state is lowered to 0 V, the potential of the word line WL in reading can be made further lower. The row control circuit 120 makes a first word-line voltage of the first word line until the sense amplifier circuit latches data of the first memory cells lower than a second word-line voltage after the sense amplifier circuit latches the data of the first memory cells.

As described above, to reduce deterioration of the characteristics by PBTI, it is preferable that Duty is made closer to 1 or is reduced. Further, to reduce deterioration of the characteristics by PBTI, a bias (the voltage Vgd or Vgs) applied to the cell transistor CT may be lowered.

For example, when the voltage of the word line WL1 illustrated in FIG. 6 is changed from 2.5 V to 1.3 V, the voltage Vgd or Vgs is lowered to 1.3 V from 2.5 V. Accordingly, it is possible to reduce deterioration of the characteristics by PBTI of the cell transistor CT.

Assuming that the word line WL1 in the period from t1 to t2_1 is in the inactive state, Duty in a case where the read command READ and the write command WRITE have been issued successively is about 0.07 ((25 ns+50 ns)/(1100 ns+25 ns+14 ns)). This is because the reliability in a case of application of 1.3 V is significantly improved as compared with a case of application of 2.5 V.

Duty in a case where the read command READ or the write command WRITE has been issued alone and reading for only one column address has been performed is about 0.53 (25 ns/(25 ns+8 ns+14 ns)).

Also in the second embodiment, Duty is very small as compared with 86 in the comparative example and close to 1. Therefore, according to the second embodiment, deterioration of the characteristics by PBTI of the cell transistor CT can be reduced. The configuration and the rest of operations of the second embodiment may be identical to the configuration and operations of the first embodiment. Accordingly, the second embodiment can obtain effects identical to those of the first embodiment.

### Third Embodiment

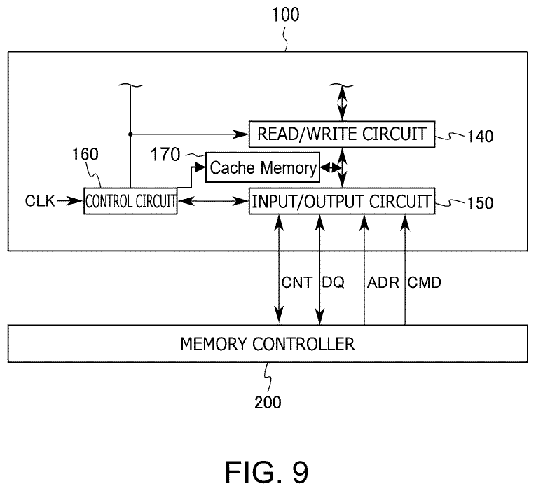

FIG. 9 is a block diagram illustrating a configuration example of the memory device 100 according to a third embodiment. The memory device 100 according to the third embodiment further includes a cache memory 170. The cache memory 170 temporarily retains data read out from the read/write circuit 140 and a row address and a column address of the first memory cell MC in which the data is stored in association with each other. Then, when data is read out from the first memory cell MC of the same row address and the same column address, the control circuit 160 reads out the data retained in the cache memory 170 to outside.

Accordingly, it is possible to reduce the number of accesses to the same first memory cell MC. In the above comparative example, when the read command READ and the write command WRITE have been issued successively by using a conventional technique, the word line WL1 is continuously made active during a period including a period from the start of burst read to the end of burst write. Even in this case, Duty can be reduced by reducing the number of accesses. Therefore, according to the third embodiment, the reduction of Duty leads to reduction of deterioration of the characteristics by PBTI.

The configuration and the rest of operations of the third embodiment may be identical to the configuration and operations of the first embodiment. Alternatively, the rest of operations of the third embodiment may be identical to operations of the above comparative example.

### Fourth Embodiment

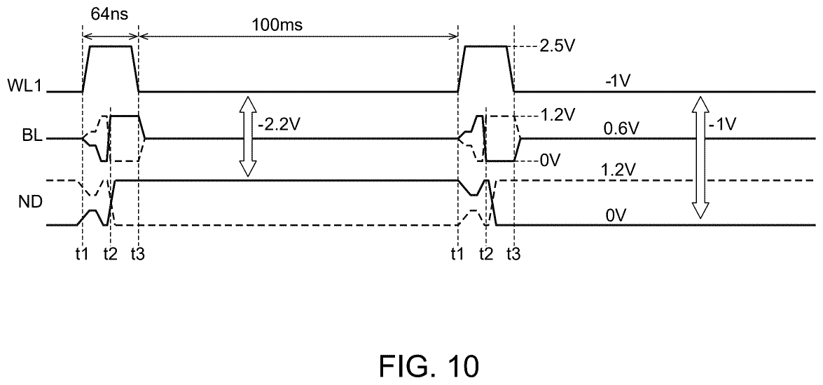

FIG. 10 is a timing chart illustrating a refresh operation of the memory device 100 according to a fourth embodiment. The refresh operation according to the fourth embodiment latches data of the first memory cells MC in the sense amplifier circuit 133 and then writes back (restores) data obtained by logic inversion of the latched data to the first memory cells MC. In the memory device 100 such as a DRAM, charges in the cell capacitor CC are lost with time even in the standby state. Therefore, the memory device 100 needs to regularly perform the refresh operation in order to maintain data in the standby state.

The memory device 100 according to the fourth embodiment performs the refresh operation in the standby state, for example, once every 100 ms. A period of the refresh operation is 64 ns, for example, and is negligibly short as compared with the cycle of the refresh operation. Therefore, in the standby state, a bias (Vgd or Vgs) applied to the cell transistor CT depends on data stored in the memory cell MC (the voltage of the node ND).

For example, in a case where the memory cell MC stores data “1” therein and the voltage of the node ND is 1.2 V as illustrated in FIG. 7, the bias applied to the cell transistor CT is −2.2 V. Meanwhile, in a case where the memory cell MC stores data “0” therein and the voltage of the node ND is 0 V, the bias applied to the cell transistor CT is −1 V. Therefore, the NBTI characteristics of the cell transistor CT storing data “1” therein are more severely deteriorated than those of the cell transistor CT storing data “0” therein.

In a case where data of the first memory cell MC is written back in a non-inverted state in the refresh operation, a bias of −2.2 V continues to be applied to the memory cell MC storing data “1” therein in the standby state. When the standby state continues for a long time, Duty on the negative bias side becomes very large, and the threshold voltage of the cell transistor CT is lowered significantly. That is, deterioration of the characteristics by NBTI of the cell transistor CT is remarkable.

In order to reduce such deterioration of the NBTI characteristics of the cell transistor CT, the data latched by the sense amplifier circuit 133 is subjected to logic inversion and is then written back (restored) to the first memory cell MC in the refresh operation in the fourth embodiment. The refresh operation is an operation of specifying row addresses in a sub array in turn and restoring data of the first memory cells MC corresponding to the respective row addresses. The refresh operation is completed by being performed for all row addresses in the sub array. In FIG. 10, one voltage is illustrated for each of the word line WL1, the bit line BL, and the node ND, for convenience's sake.

For example, in the example of FIG. 10, it is assumed that the first memory cell MC stores therein data “0” represented with a solid line before t1.

At t1, the row control circuit 120 activates the word line WL1 corresponding to a certain row address for the refresh operation. Accordingly, data stored in the first memory cell MC is transmitted to the bit line BL. In a case where the first memory cell MC stores data “0” therein (solid line), the voltage (e.g., 0 V) of the node ND is transmitted to the bit line BL. In a case where the first memory cell MC stores data “1” therein (broken line), the voltage (e.g., 1.2 V) of the node ND is transmitted to the bit line BL.

The sense amplifier circuit 133 detects and latches the data of each first memory cell MC via the bit line BL.

At t2, the read/write circuit 140 inverts the data of each first memory cell MC latched by the sense amplifier circuit 133. By latching the inverted data by the sense amplifier circuit 133, each first memory cell MC stores the inverted data therein.

At t3, the row control circuit 120 deactivates the word line WL1 corresponding to that row address after the data of each of the first memory cells MC corresponding to that row address is inverted in the sense amplifier circuit 133. Accordingly, the refresh operation for that row address is finished.

Although not illustrated, the memory device 100 then performs the refresh operation for the memory cells MC corresponding to the next row address.

The refresh operation is performed for the memory cells MC of all row addresses in row address order in the manner described above, whereby one refresh operation is completed.

Thereafter, the standby state continues for about 100 ms, for example, and then the next refresh operation is performed. In the next refresh operation, the inverted data stored in each memory cell MC is further inverted. Therefore, each memory cell MC stores the original data (non-inverted data) therein.

As described above, in the fourth embodiment, data of each memory cell MC is inverted and written back every time the refresh operation is performed. Consequently, in the standby state, each memory cell MC stores data “1” and data “0” therein for almost 50% of the time each. That is, Duty of data “1” and data “0” is almost 1. This result leads to reduction of deterioration of the characteristics by NBTI.

In the example of FIG. 10, for data “1” and data “0”, voltages applied to the cell transistor CT are both negative values (−2.2 V and −1 V). Therefore, although deterioration of the characteristics by NBTI cannot be avoided, the amount of fluctuation in the threshold voltage of the memory cell MC is significantly reduced as compared with a fluctuation in the threshold voltage of the memory cell MC to which −2.2 V (data “1”) continues to be applied in the standby state. Consequently, the lifetime of the memory device 100 as a whole can be prolonged.

Further, it can be considered that, every time access is made in a normal read operation or a normal write operation, data of the memory cell MC is inverted and restored as described above. However, since random access is made in this case, Duty does not always approach 1. That is, the fluctuation in the threshold voltage of the memory cell MC may become large and there is a possibility that the characteristics are adversely deteriorated by NBTI. Further, the access speed and power consumption also become worse. Furthermore, for each row address, it is necessary to store a flag indicating inversion/non-inversion and read out that flag.

Meanwhile, the memory device 100 according to the fourth embodiment inverts and restores data of the memory cell MC in each refresh operation performed regularly in the standby state. Therefore, Duty becomes approximately 1. That is, it is possible to make the fluctuation in the threshold voltage of the memory cell MC small and reduce deterioration of the characteristics by NBTI.

In the fourth embodiment, the flag indicating inversion/non-inversion is necessary. However, the refresh operation is performed for the entire memory cell array 110 or the entire sub array (111A or 111B). Therefore, the flag indicating inversion/non-inversion only requires 1-bit data for the memory cell array 110 or each sub array. This flag indicates whether data of the memory cells MC in the memory cell array 110 or each sub array is to be inverted from original data to reverse-logic data or from the reverse-logic data to the original data. It suffices that this flag indicates up to which word line the memory cells MC thereof have been refreshed so far as described below. As for this flag (1-bit data), it suffices that one flag is stored for the memory cell array 110 or for each of the sub arrays 111A and 111B. This flag may be stored in a memory (not illustrated) in the control circuit 160, for example, a Flip-Flop or the like of a peripheral circuit. As described above, in the fourth embodiment, although the flag indicating inversion/non-inversion is necessary, the number of bits thereof is very small and the flag has almost no influence on the data capacity of the memory cell array 110.

In addition, in a case where the refresh operation is performed while specifying row addresses in turn, the memory device 100 needs to retain the refreshed row address for which the latest refresh operation has been performed (the latest row address). Since a row address to be refreshed is retained in a DRAM originally, the data capacity does not increase if the flag is included in the row address. The row address to be refreshed can be stored in a memory (not illustrated) in the control circuit 160, for example, a Flip-Flop or the like of a peripheral circuit.

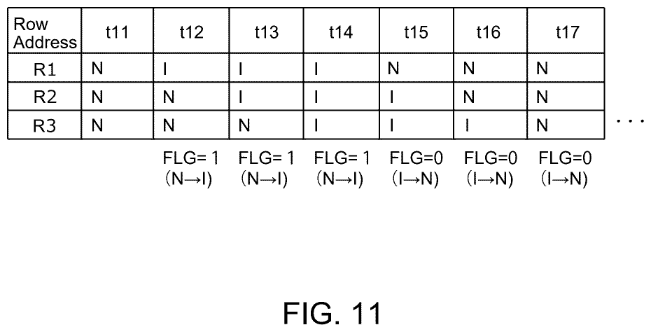

FIG. 11 is a table representing an example of a refresh operation according to the fourth embodiment. The table of FIG. 11 represents refresh operations for row addresses R1 to R3. In a case where a flag FLG is 1, it indicates a refresh operation from a non-inverted state N to an inverted state I. In a case where the flag FLG is 0, it indicates a refresh operation from the inverted state I to the non-inverted state N. That is, in a case where the flag FLG is 1, the memory cell MC of the memory cell array 110 stores original data (non-inverted data) therein. In a case where the flag FLG is 0, the memory cell MC of the memory cell array 110 stores data obtained by inverting the original data (inverted data) therein.

A state at T11 represents a state before a refresh operation.

At t12, a refresh operation of the first memory cells MC corresponding to the row address R1 is performed. Accordingly, data of the row address R1 is inverted from the non-inverted state N to the inverted state I. At this time, data of the row address R1 and data of the flag FLG are retained in a memory.

At t13, a refresh operation of the first memory cells MC corresponding to the row address R2 is performed. Accordingly, data of the row address R2 is inverted from the non-inverted state N to the inverted state I. At this time, data of the row address R2 and the data of the flag FLG are retained in the memory.

At t14, a refresh operation of the first memory cells MC corresponding to the row address R3 is performed. Accordingly, data of the row address R3 is inverted from the non-inverted state N to the inverted state I. At this time, data of the row address R3 and the data of the flag FLG are retained in the memory.

When the refresh operations for all the row addresses R1 to R3 are finished, the flag FLG is changed from 1 to 0. Accordingly, it is found that the memory cells MC of the memory cell array 110 store data obtained by

Inverting the original data (inverted data) therein.

At t15, the refresh operation of the first memory cells MC corresponding to the row address R1 is performed. Accordingly, the data of the row address R1 is inverted from the inverted state I to the non-inverted state N (returns to the original data). At this time, the data of the row address R1 and the data of the flag FLG are retained in the memory.

At t16, the refresh operation of the first memory cells MC corresponding to the row address R2 is performed. Accordingly, the data of the row address R2 is inverted from the inverted state I to the non-inverted state N (returns to the original data). At this time, the data of the row address R2 and the data of the flag FLG are retained in the memory.

At t17, the refresh operation of the first memory cells MC corresponding to the row address R3 is performed. Accordingly, the data of the row address R3 is inverted from the inverted state I to the non-inverted state N (returns to the original data). At this time, the data of the row address R3 and the data of the flag FLG are retained in the memory.

Consequently, the state of the data returns to the initial state of t11. When the refresh operations for all the row addresses R1 to R3 are finished, the flag FLG is changed from 0 to 1. Accordingly, it is found that the memory cells MC of the memory cell array 110 store the original data (non-inverted data) therein.

Thereafter, processes at T12 to T17 are repeated.

As one method, a read operation and a write operation are performed after completion of the refresh operations for all the row addresses R1 to R3 (after inversion of FLG). In a case where the flag FLG is 1 at this time, it suffices that, regarding the memory cell array 110 as storing original non-inverted data therein, the stored data is read and written as it is. In a case where the flag FLG is 0, it suffices that, regarding that the memory cell array 110 as storing inverted data therein, the stored data is inverted (is restored to original data) and is read and written.

As another method, it is also possible to perform a read operation and a write operation between refresh operations of the respective word lines WL. In this case, only the row address up to which the refresh operation has been done and which is currently stored in the memory, the data of the flag FLG, and a row address for which a normal random-access read operation and a normal random-access write operation are to be performed are required. For example, in a case where refreshing has been done up to t13 and the refreshed address is R2, the flag FLG is 1. Therefore, in a case where an address number of a normal random access is the refreshed address R2 or smaller, that is, the address number of the random access is R1 or R2, stored data can be determined as inverted data. In a case where the address number of the random access is larger than the refreshed address R2, that is, the address number of the random access is R3, the stored data can be determined as non-inverted data. Similarly, in a case where refreshing has been done up to t15 and the refreshed address is R1, for example, the flag FLG is 0. Therefore, in a case where the address number of the normal random access is the refreshed address R1 or smaller, that is, the address number of the random access is R1, the stored data can be determined as non-inverted data. In a case where the address number of the normal random access is larger than the refreshed address R1, that is, the address number of the random access is R2 or R3, the stored data can be determined as inverted data.

The fourth embodiment can be combined with any of the first to third embodiments. Accordingly, both deterioration of the characteristics by PBTI and that by NBTI can be reduced.

### Fifth Embodiment

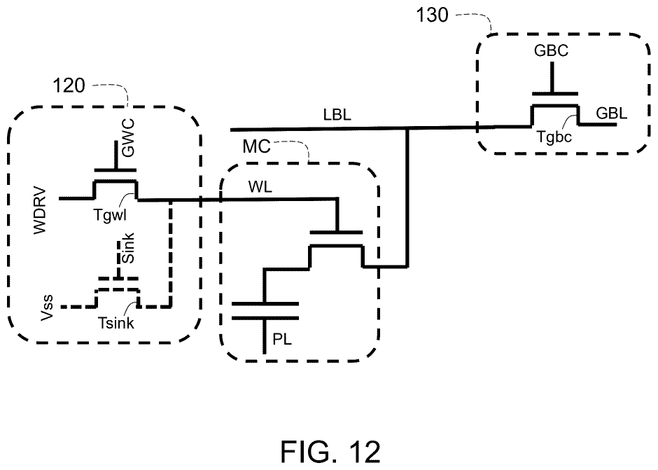

FIG. 12 is a block diagram illustrating a configuration example of the row control circuit 120, the column control circuit 130, and the memory cell MC according to a fifth embodiment. According to the fifth embodiment, oxide semiconductor is used for a channel region of a transistor constituting each of the row control circuit 120 and the column control circuit 130 as well as the memory cell MC.

Each of transistors Tgwl and Tsink constituting the row control circuit 120 is a transistor driving the voltage of the word line WL. The transistor Tgwl applies the voltage of a word driving line WDRV to the word line WL (the gate of the cell transistor CT) in accordance with a control signal GWC. The transistor Tsink applies the voltage of a reference voltage source Vss to the word line WL in accordance with a control signal Sink. In a case where oxide semiconductor is used for the channel region of each of the transistors Tgwl and Tsink, there are concerns about deterioration of the characteristics thereof. Therefore, the gate voltages GWC and Sink of the transistors Tgwl and Tsink according to the fifth embodiment are pulsed, similarly to the word line WL. Accordingly, Duty of each of the transistors Tgwl and Tsink can be reduced, so that deterioration of the characteristics by PBTI can be reduced. For example, to make the voltage of the word line WL high, the transistor Tgwl is made conducting (turned on) only for a short time, and thereafter the transistor Tgwl is made non-conducting (turned off). With this operation, the word line WL is placed in a high-voltage state and in an electrically floating state. In order to make the voltage of the word line WL low, the transistor Tsink is turned on only for a short time, and thereafter the transistor Tsink is turned off. With this operation, the word line WL is placed in a low-voltage state and in the electrically floating state. In a case where both the transistors Tgwl and Tsink are turned off in the standby state or the like and the voltage of the word line WL in the floating state fluctuates unstably, it suffices that a short pulse is supplied to the transistor Tsink regularly to maintain the word line WL in the low-voltage state.

When the word line WL is disconnected from the word driving line WDRV, the word line WL is in the electrically floating state. Therefore, even when the transistor Tgwl is pulsed, the voltage of the word line WL is maintained to the voltage of the word driving line WDRV until the transistor Tsink is turned on. Further, even when the transistor Tsink is pulsed, by connecting the reference voltage source Vss (or a negative voltage source) to the word line WL, it is possible to lower the voltage of the word line WL to Vss (or a negative voltage). Therefore, there is no problem if the transistors Tgwl and Tsink are pulsed.

For example, the gate voltage GWC of the transistor Tgwl is 3.5 V in the active state and −0.5 V in the inactive state. In this case, by pulsing the transistor Tgwl, it is possible to reduce Duty of the transistor Tgwl and reduce deterioration of the characteristics by PBTI. The same applies to the transistor Tsink.

In a case where the inactive period of the transistor Tgwl is much longer than the active period, it is preferable that the gate voltage GWC in the inactive state is a low negative voltage (low as an absolute value) or is close to 0 V (no bias). Accordingly, Duty of the transistor Tgwl can be reduced, so that deterioration of the characteristics by PBTI can be reduced. In a case where the active period of the transistor Tgwl is equivalent to the inactive period, it is preferable that the gate voltage GWC of the transistor Tgwl has reverse polarities in the active state and the inactive state. Accordingly, Duty of the transistor Tgwl can be reduced, so that deterioration of the characteristics by PBTI can be reduced.

In a case where the memory cell array 110 is a three-dimensional array in which the memory cells MC are arranged three-dimensionally, the configuration of bit lines may have a hierarchical bit line configuration in which one global bit line GBL is provided for a plurality of local bit lines LBL. In this case, a selection transistor Tgbc is connected between each local bit line LBL and the global bit line GBL. The transistors Tgbc constituting the column control circuit 130 selectively connect one of the local bit lines LBL which is specified by a column address to the global bit line GBL. In a case of using oxide semiconductor for the selection transistor Tgbc, the column control circuit 130 pulses the gate voltage of the selection transistor Tgbc for a short time only when necessary. Accordingly, Duty of the transistor Tgbc can be reduced, so that deterioration of the characteristics by PBTI can be reduced.

For example, a gate voltage GBC of the transistor Tgbc is 2.5 V in the active state and −0.5 V in the inactive state. In this case, by pulsing the transistor Tgbc, it is possible to reduce Duty of the transistor Tgbc and reduce deterioration of the characteristics by PBTI. As described above, to reduce a fluctuation in the threshold voltage by PBTI and NBTI, it is preferable to set the voltages Vgs and Vds to positive voltages when the transistor Tgbc is in an on-state and to negative voltages when the transistor Tgbc is in an off-state, and to combine the positive voltage and the negative voltage.

This configuration can reduce deterioration of the row control circuit 120 and the column control circuit 130 as well as the memory cell array 110, so that the lifetime of the memory device 100 can be prolonged.

In a case where the inactive period of the transistor Tgbc is much longer than the active period, it is preferable that the gate voltage GBC in the inactive state is a low negative voltage (low as an absolute value) or is close to 0 V (no bias). Accordingly, Duty of the transistor Tgbc can be reduced, so that deterioration of the characteristics by PBTI can be reduced. In a case where the active period of the transistor Tgbc is equivalent to the inactive period, it is preferable that the gate voltage GBC of the transistor Tgbc has reverse polarities in the active state and the inactive state. Accordingly, Duty of the transistor Tgbc can be reduced, so that deterioration of the characteristics by PBTI can be reduced.

The fifth embodiment can be combined with any of the first to fourth embodiments. Accordingly, characteristics deterioration of each of the memory cell array 110, the row control circuit 120, and the column control circuit 130 can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a plurality of word lines;
a plurality of bit lines;
a plurality of memory cells provided to correspond to crossing positions of the word lines and the bit lines and formed by using oxide semiconductor;
a word-line control circuit configured to change a voltage of a first word line selected from the word lines in accordance with a first address to activate or deactivate the first word line;
a sense amplifier circuit connected to the bit lines and configured to detect and latch data of a plurality of first memory cells connected to the first word line; and
a read circuit configured to read out data latched by the sense amplifier circuit to outside successively in accordance with a plurality of second addresses, wherein in a read operation, the sense amplifier circuit latches the data of the first memory cells after activation of the first word line, and
the word-line control circuit deactivates the first word line before the read circuit ends a successive read operation of successively reading out the data of the first memory cells from the sense amplifier circuit in accordance with the second addresses.

2. The device of claim 1, further comprising a write circuit configured to cause the sense amplifier circuit to latch data from outside successively in accordance with the second addresses, wherein
in a write operation, the word-line control circuit activates again the first word line before the write circuit ends a successive write operation of successively latching the data from the outside in accordance with the second addresses.

3. The device of claim 2, wherein in a write operation, the word-line control circuit activates again the first word line after the write circuit starts the successive write operation.

4. The device of claim 2, wherein in a case of performing a write operation, the word-line control circuit maintains the first word line in an inactive state after the data of the first memory cells is latched by the sense amplifier circuit until the write circuit starts the successive write operation.

5. The device of claim 1, wherein each of the memory cells includes
a transistor having a gate connected to any of the word lines, a source and a drain one of which is connected to any of the bit lines, and a channel region including the oxide semiconductor, and
a capacitor connected to the other of the source and the drain of the transistor.

6. The device of claim 2, wherein each of the memory cells includes
a transistor having a gate connected to any of the word lines, a source and a drain one of which is connected to any of the bit lines, and a channel region including the oxide semiconductor, and
a capacitor connected to the other of the source and the drain of the transistor.

7. The device of claim 1, wherein the word-line control circuit sets a voltage of the first word line until the sense amplifier circuit detects the data of the first memory cells to be lower than a voltage of the first word line after the sense amplifier circuit latches the data of the first memory cells.

8. The device of claim 1, further comprising a memory configured to temporarily retain data corresponding to the first and second addresses which has been read out from the read circuit, wherein
when the data corresponding to the first and second addresses is read out, the data retained in the memory is read out to outside.

9. The device of claim 1, wherein the word-line control circuit makes a voltage of a word line other than the first word line among the word lines reverse to the voltage of the first word line in polarity.

10. The device of claim 1, wherein the word-line control circuit includes a driver configured to drive the voltage of the first word line to a positive polarity and another driver configured to drive the voltage of the first word line to a negative polarity, and also includes a circuit configured to make the first word line floating for a longer time than a time during which the first word line is driven to a positive polarity or a negative polarity.

11. The device of claim 1, wherein the word-line control circuit includes a transistor having a channel region including oxide semiconductor.

12. The device of claim 1, wherein
the bit lines correspond to one global bit line, and a selection transistor is further included to be connected between each of the bit lines and the global bit line, and
the selection transistor has a channel region including oxide semiconductor and is driven in such a manner that a gate voltage thereof changes between two potentials different in polarity from each other.

13. A semiconductor storage device comprising:
a plurality of memory cells provided to correspond to crossing positions of a plurality of word lines and a plurality of bit lines and formed by using oxide semiconductor;
a word-line control circuit configured to change a voltage of a first word line selected from the word lines in accordance with a first address to activate or deactivate the first word line;
a sense amplifier circuit connected to the bit lines and configured to detect and latch data of a plurality of first memory cells connected to the first word line and, after latching, perform a restore operation of writing back the data to the first memory cells;
a read circuit configured to successively read out data latched by the sense amplifier circuit to outside in accordance with a plurality of second addresses; and
a write circuit configured to successively write the data latched by the sense amplifier circuit in accordance with a plurality of second addresses, wherein
in the restore operation in a refresh instruction by an internally generated signal or an external signal, the data of each of the first memory cells latched by the sense amplifier circuit is inverted and written back to the first memory cells.

14. The device of claim 13, further comprising a storage configured to store therein a flag indicating, in the restore operation in the refresh instruction, whether the data of the first memory cells is to be inverted from original data to reverse-logic data or is to be changed from the reverse-logic data to the original data.

15. The device of claim 13, further comprising a storage configured to, in a case where the restore operation is performed while the word lines are specified in turn in accordance with the first address, store therein a restored first address for which the restore operation in the refresh instruction has been performed most recently.

16. The device of claim 13, wherein the word-line control circuit makes a voltage of a word line other than the first word line among the word lines reverse to the voltage of the first word line in polarity.

17. The device of claim 13, wherein the word-line control circuit includes a driver configured to drive the voltage of the first word line to a positive polarity and another driver configured to drive the voltage of the first word line to a negative polarity, and also includes a circuit configured to make the first word line floating for a longer time than a time during which the first word line is driven to a positive polarity or a negative polarity.

18. The device of claim 13, wherein the word-line control circuit includes a transistor having a channel region including oxide semiconductor.

19. The device of claim 13, wherein
the bit lines correspond to one global bit line, and a selection transistor is further included to be connected between each of the bit lines and the global bit line, and
the selection transistor has a channel region including oxide semiconductor and is driven in such a manner that a gate voltage thereof changes between two potentials different in polarity from each other.

20. The device of claim 13 wherein each of the memory cells includes
a transistor having a gate connected to any of the word lines, a source and a drain one of which is connected to any of the bit lines, and a channel region including the oxide semiconductor, and
a capacitor connected to the other of the source and the drain of the transistor.

21. The device of claim 16, wherein each of the memory cells includes
a transistor having a gate connected to any of the word lines, a source and a drain one of which is connected to any of the bit lines, and a channel region including the oxide semiconductor, and
a capacitor connected to the other of the source and the drain of the transistor.

22. The device of claim 17, wherein each of the memory cells includes
a transistor having a gate connected to any of the word lines, a source and a drain one of which is connected to any of the bit lines, and a channel region including the oxide semiconductor, and
a capacitor connected to the other of the source and the drain of the transistor.

23. The device of claim 18, wherein each of the memory cells includes
a transistor having a gate connected to any of the word lines, a source and a drain one of which is connected to any of the bit lines, and a channel region including the oxide semiconductor, and
a capacitor connected to the other of the source and the drain of the transistor.

24. The device of claim 19, wherein each of the memory cells includes
a transistor having a gate connected to any of the word lines, a source and a drain one of which is connected to any of the bit lines, and a channel region including the oxide semiconductor, and
a capacitor connected to the other of the source and the drain of the transistor.
